(19) United States
(12) Patent Application Publication
(10) Pub. No.: US 2024/0088191 A1
(43) Pub. Date: Mar. 14, 2024

(54) PHOTOELECTRIC CONVERSION DEVICE AND ELECTRONIC APPARATUS

(71) Applicant: SONY SEMICONDUCTOR SOLUTIONS CORPORATION, Kanagawa (JP)

(72) Inventors: Kazuki NOMOTO, Kanagawa (JP); Hiroaki AMMO, Kanagawa (JP)

(73) Assignee: SONY SEMICONDUCTOR SOLUTIONS CORPORATION, Kanagawa (JP)

(21) Appl. No.: 18/263,928

(22) PCT Filed: Jan. 19, 2022
(86) PCT No.: PCT/JP2022/001854

§ 371 Date: Aug. 2, 2023

(30) Foreign Application Priority Data
Feb. 12, 2021 (JP) 2021-020561

(51) Int. Cl. H01L 27/146

(52) U.S. Cl. CPC H01L 27/14638; H01L 27/14612; H01L 27/1463; H01L 27/14636

(57) ABSTRACT

A photoelectric conversion device according to an embodiment of the present disclosure includes: a first semiconductor layer in which a transfer transistor is provided; a second semiconductor layer in which a pixel transistor is provided; and a wiring layer in which a gate wiring line coupled to a gate of the transfer transistor is provided. A portion or all of the pixel transistor is disposed, in plan view, in a region between a first gate wiring line and a second gate wiring line. The first gate wiring line is coupled to the gate of the transfer transistor in one of two pixels adjacent to each other. The second gate wiring line is coupled to the gate of the transfer transistor in another of the two pixels adjacent to each other.

### TECHNICAL FIELD

The present disclosure relates to a photoelectric conversion device and an electronic apparatus.

### BACKGROUND ART

Typically, in a solid-state imaging device having a two-dimensional structure, the area of one pixel has been reduced by introducing a miniaturization process and improving mounting density. In recent years, a solid-state imaging device having a three-dimensional structure has been developed in order to further miniaturize the solid-state imaging device and increase density of pixels. In the solid-state imaging device having a three-dimensional structure, for example, a semiconductor substrate including multiple photoelectric converters and a semiconductor substrate including an amplification transistor are stacked on each other. The amplification transistor generates a signal having a voltage corresponding to a level of charge obtained at each of the photoelectric converters (see, for example, PTL 1).

### CITATION LIST

### Patent Literature

PTL1: International Publication No. WO2019/131965

### SUMMARY OF THE INVENTION

Incidentally, in a case of an existing solid-state imaging device, as density of pixels increases, signals within pixels can interfere with each other, possibly leading to a deterioration in a noise characteristic. Such a problem is not limited to the solid-state imaging device but also can occur in a photoelectric conversion device in general. It is thus desirable to provide a photoelectric conversion device and an electronic apparatus that make it possible to suppress deterioration in a noise characteristic.

A photoelectric conversion device according to a first aspect of the present disclosure includes a first semiconductor layer, a second semiconductor layer stacked on the first semiconductor layer, and a wiring layer provided between the first semiconductor layer and the second semiconductor layer. In the first semiconductor layer, a photoelectric converter, a charge accumulation section, and a transfer transistor are provided for each of pixels. The charge accumulation section accumulates signal charge generated at the photoelectric converter. The transfer transistor transfers the signal charge from the photoelectric converter to the charge accumulation section. In the second semiconductor layer, a pixel transistor is provided for each unit of one or more of the pixels. The pixel transistor reads out the signal charge from the charge accumulation section. In the wiring layer, an interlayer insulating film and a gate wiring line are provided. The gate wiring line is provided within the interlayer insulating film, and is coupled to a gate of the transfer transistor for each of the pixels. The pixel transistor is disposed, in plan view, in a region between a first gate wiring line and a second gate wiring line. The first gate wiring line is coupled to the gate of the transfer transistor included in a first pixel. The second gate wiring line is coupled to the gate of the transfer transistor included in a second pixel. The first pixel and the second pixel are two of the pixels and are adjacent to each other.

An electronic apparatus according to a second aspect of the present disclosure includes the photoelectric conversion device described above.

In the photoelectric conversion device according to the first aspect of the present disclosure and the electronic apparatus according to the second aspect of the present disclosure, the pixel transistor is disposed in the region between the first gate wiring line and the second gate wiring line in plan view. This reduces a possibility that a signal applied to the first gate wiring line or the second gate wiring line interferes with the pixel transistor, for example, as compared with a case where the first gate wiring line or the second gate wiring line is disposed directly below the pixel transistor.

### BRIEF DESCRIPTION OF DRAWINGS

FIG. 1 is a diagram illustrating an example of a schematic configuration of a solid-state imaging device according to an embodiment of the present disclosure.

FIG. 2 is a diagram illustrating an example of a circuit configuration of a sensor pixel and a reading circuit in FIG. 1.

FIG. 3 is a diagram illustrating an example of a cross-sectional configuration of a solid-state imaging device in FIG. 1.

FIG. 4 is a diagram illustrating an example of the cross-sectional configuration of the solid-state imaging device in FIG. 1.

FIG. 5 is a diagram illustrating an example of a cross-sectional configuration at Sec1 in FIGS. 3 and 4.

FIG. 6 is a diagram illustrating an example of a cross-sectional configuration at Sec2 in FIGS. 3 and 4.

FIG. 7A is a diagram illustrating an example of the cross-sectional configuration during a process of manufacturing the solid-state imaging device in FIG. 1.

FIG. 7B is a diagram illustrating an example of the cross-sectional configuration of a process following that in FIG. 7A.

FIG. 7C is a diagram illustrating an example of the cross-sectional configuration of a process following that in FIG. 7B.

FIG. 7D is a diagram illustrating an example of the cross-sectional configuration of a process following that in FIG. 7C.

FIG. 7E is a diagram illustrating an example of the cross-sectional configuration of a process following that in FIG. 7D.

FIG. 7F is a diagram illustrating an example of the cross-sectional configuration of a process following that in FIG. 7E.

FIG. 7G is a diagram illustrating an example of the cross-sectional configuration of a process following that in FIG. 7F.

FIG. 7H is a diagram illustrating an example of the cross-sectional configuration of a process following that in FIG. 7G.

FIG. 7I is a diagram illustrating an example of the cross-sectional configuration of a process following that in FIG. 7H.

FIG. 7J is a diagram illustrating an example of the cross-sectional configuration of a process following that in FIG. 7I.

FIG. 7K is a diagram illustrating an example of the cross-sectional configuration of a process following that in FIG. 7J.

FIG. 8 is a diagram illustrating a modification example of the cross-sectional configuration of the solid-state imaging device in FIG. 1.

FIG. 9 is a diagram illustrating an example of the cross-sectional configuration at Sec1 in FIG. 8.

FIG. 10 is a diagram illustrating an example of the cross-sectional configuration at Sec2 in FIG. 8.

FIG. 11 is a diagram illustrating a modification example of the cross-sectional configuration in FIG. 5.

FIG. 12 is a diagram illustrating a modification example of the cross-sectional configuration in FIG. 6.

FIG. 13 is a diagram illustrating a modification example of a wiring line coupled to the sensor pixel in FIG. 1.

FIG. 14 is a diagram illustrating a modification example of the wiring line coupled to the sensor pixel in FIG. 1.

FIG. 15 is a diagram illustrating a modification example of the cross-sectional configuration in FIG. 9.

FIG. 16 is a diagram illustrating a modification example of the cross-sectional configuration in FIG. 10.

FIG. 17 is a diagram illustrating a modification example of the circuit configuration of the sensor pixel and the reading circuit in FIG. 1.

FIG. 18 is a diagram illustrating a modification example of a cross-sectional configuration of an amplification transistor in FIG. 4.

FIG. 19 is a diagram illustrating an example of a schematic configuration of an imaging system including the solid-state imaging device according to the embodiment described above and the modification examples thereof.

FIG. 20 is a block diagram depicting an example of schematic configuration of a vehicle control system.

FIG. 21 is a diagram of assistance in explaining an example of installation positions of an outside-vehicle information detecting section and an imaging section.

FIG. 22 is a view depicting an example of a schematic configuration of an endoscopic surgery system.

FIG. 23 is a block diagram depicting an example of a functional configuration of a camera head and a camera control unit (CCU).

### MODES FOR CARRYING OUT THE INVENTION

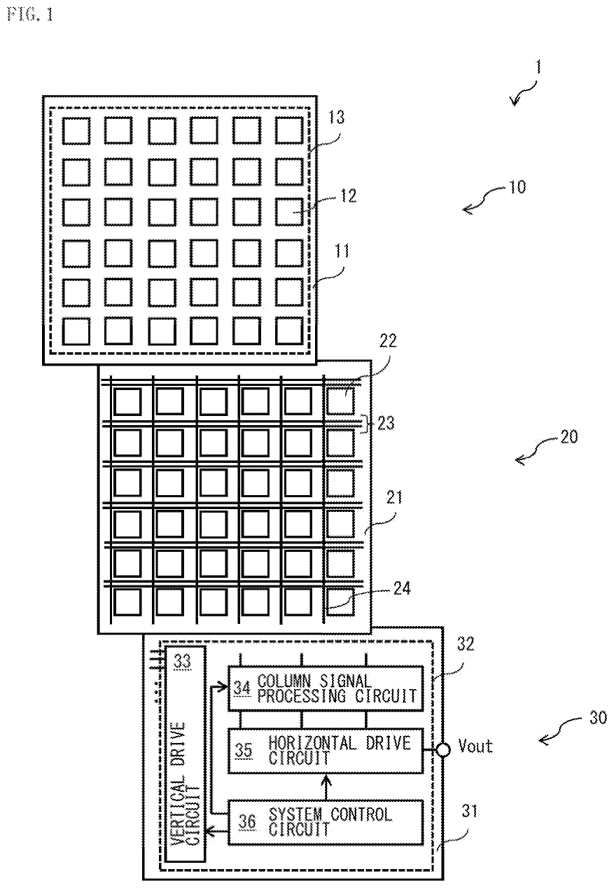

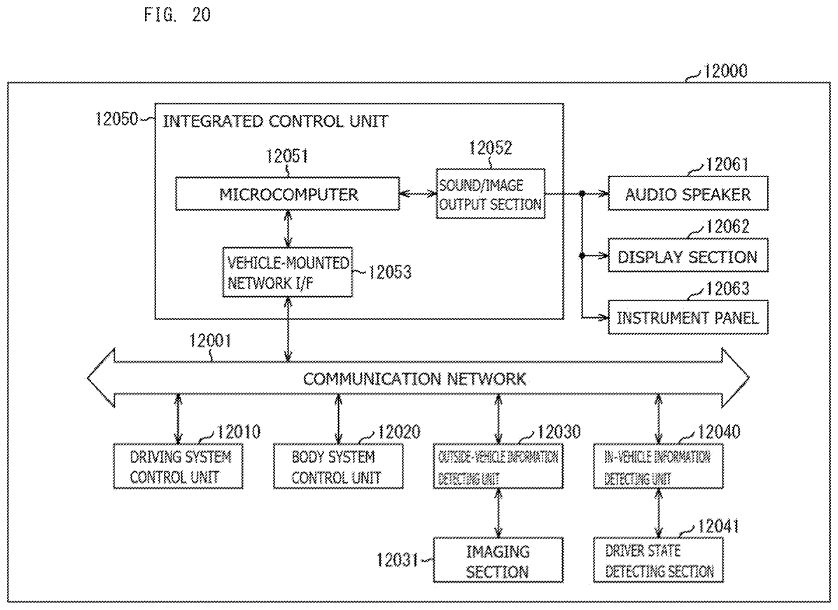

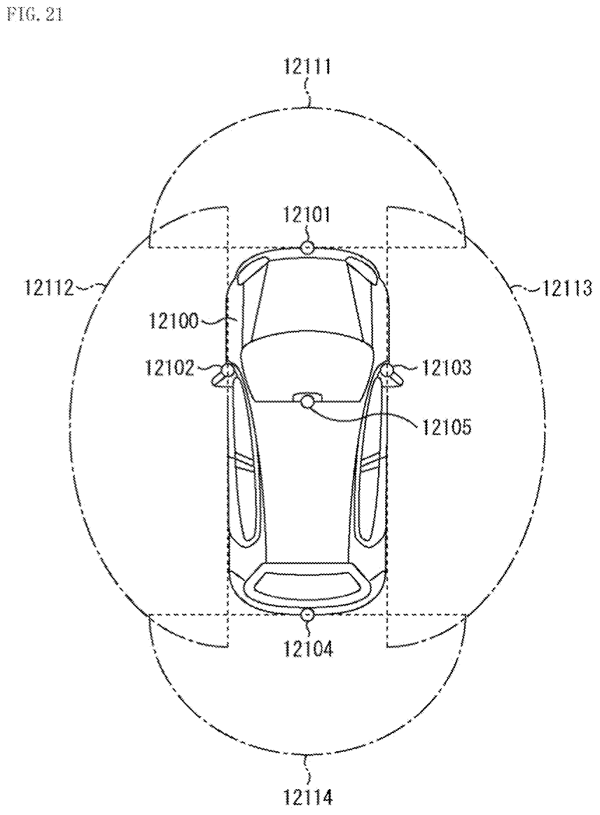

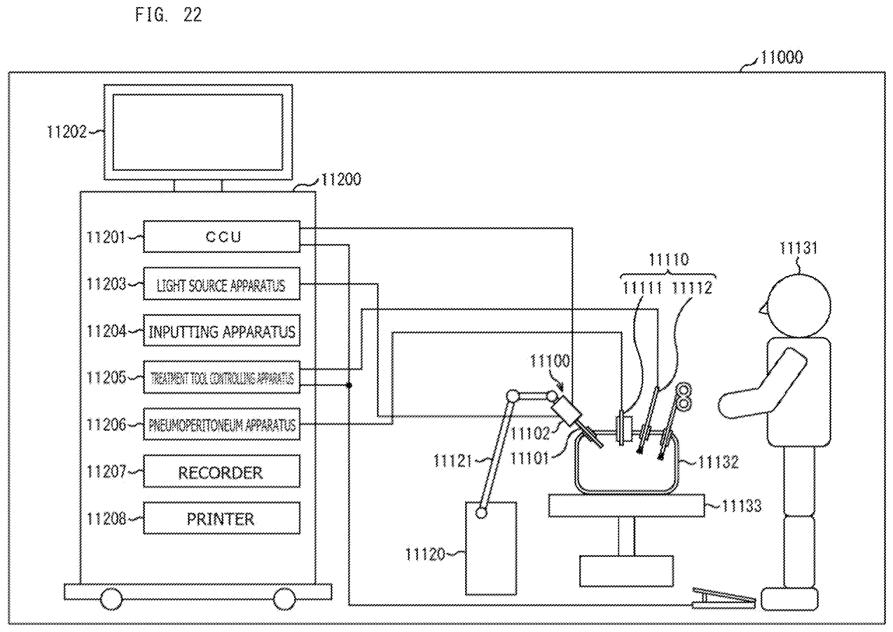

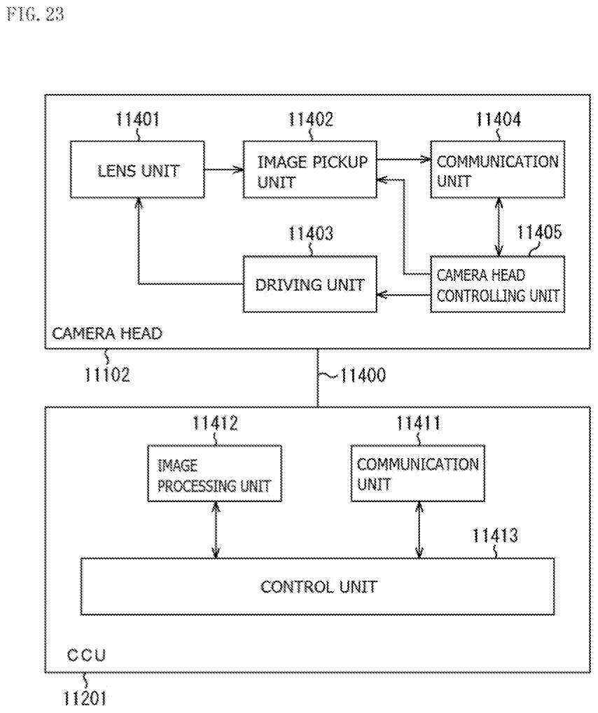

An embodiment according to the present disclosure will be described below in detail with reference to the drawings. Note that a description will be given in the following order.
1. Embodiment (Solid-state Imaging Device) FIG. 1 to FIG. 7
2. Modification Examples (Solid-state Imaging Device) FIG. 8 to FIG. 18
3. Application Example (Imaging System) FIG. 19
4. Practical Application Examples
   Practical Application Example 1 (Mobile Body) FIG. 20 and FIG. 21
   Practical Application Example 2 (Surgical Operation System) FIG. 22 and FIG. 23

### 1. Embodiment

### [Configuration]

A solid-state imaging device 1 according to an embodiment of the present disclosure will be described. The solid-state imaging device 1 is, for example, a back-illuminated imaging sensor including a CMOS (Complementary Metal Oxide Semiconductor) imaging sensor or the like. The solid-state imaging device 1 receives light from a subject, and perform photoelectric conversion on it to generate an image signal, thereby capturing an image. The solid-state imaging device 1 outputs a pixel signal corresponding to the incident light.

The back-illuminated imaging sensor is an imaging sensor in which a photoelectric converter is provided between a light receiving surface into which light from a subject enters and a wiring layer in which a wiring line for a transistor or the like that drives each pixel is provided. The photoelectric converter is a photodiode or the like that receives light from a subject and converts it into an electrical signal. Note that the present disclosure is not limitedly applied to the CMOS imaging sensor.

FIG. 1 is a diagram illustrating an example of a schematic configuration of the solid-state imaging device 1 according to the embodiment of the present disclosure. The solid-state imaging device 1 includes three substrates (a first substrate 10, a second substrate 20, and a third substrate 30). The solid-state imaging device 1 is an imaging unit having a three-dimensional structure configured such that the three substrates (the first substrate 10, the second substrate 20, and the third substrate 30) are bonded together. The first substrate 10, the second substrate 20, and the third substrate 30 are stacked in this order.

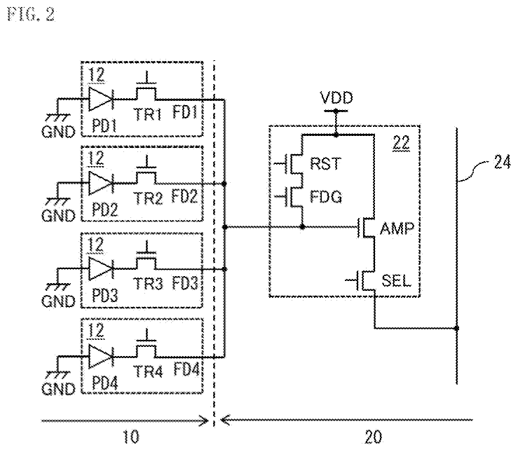

The first substrate 10 includes a pixel region 13 in which multiple sensor pixels 12 that perform photoelectric conversion are arrayed in a matrix manner. The pixel region 13 is provided in the semiconductor substrate 11. The second substrate 20 includes multiple reading circuits 22 that each output a pixel signal based on charge (signal charge) outputted from the sensor pixel 12. Note that, in the solid-state imaging device 1, one set of the sensor pixel 12 and the reading circuit 22 is sometimes referred to as an imaging pixel. The multiple reading circuits 22 are provided in the semiconductor substrate 21, and for example, each of the reading circuits 22 is allocated to corresponding unit of multiple sensor pixels 12 as illustrated in FIG. 2. In this case, one reading circuit 22 is shared by multiple imaging pixels.

The second substrate 20 includes multiple pixel driving lines 23 extending in a row direction and multiple vertical signal lines 24 extending in a column direction. The third substrate 30 includes a logic circuit 32 that processes the pixel signal. The logic circuit 32 is provided in a semiconductor substrate 31. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs, to an outside, an output voltage Vout for each of the sensor pixels 12.

The vertical drive circuit 33 sequentially selects the multiple sensor pixels 12 on a row basis, for example. The column signal processing circuit 34 performs a correlated double sampling (CDS) process on a pixel signal outputted from each of the sensor pixels 12 in a row selected by the vertical drive circuit 33, for example. For example, by performing the CDS process, the column signal processing circuit 34 extracts a signal level of the pixel signal to hold pixel data corresponding to the amount of received light at each of the sensor pixels 12. The horizontal drive circuit 35 sequentially outputs, to the outside, the pixel data held at the column signal processing circuit 34, for example. The system control circuit 36 controls driving of each of the blocks (the vertical drive circuit 33, the column signal processing circuit 34, and the horizontal drive circuit 35) within the logic circuit 32, for example.

FIG. 2 is a diagram illustrating an example of the sensor pixel 12 and the reading circuit 22. A description will be given below of a case where one reading circuit 22 is shared by four sensor pixels 12 as illustrated in FIG. 2. Here, the term “share” means that outputs from the four sensor pixels 12 are supplied to the common reading circuit 22.

Each of the sensor pixels 12 includes components the same as each other. In FIG. 2, identification numbers (1, 2, 3, and 4) are attached to the end of the reference characters of components of the respective sensor pixels 12 in order to distinguish the components of the respective sensor pixels 12 from each other. Below, in a case where the components of the respective sensor pixels 12 need to be distinguished from each other, the identification numbers are attached to the end of the reference characters of the components of the respective sensor pixels 12. Meanwhile, in a case where the components of the respective sensor pixels 12 do not need to be distinguished from each other, the identification numbers at the end of the reference characters of the components of the respective sensor pixels 12 are omitted.

Each of the sensor pixels 12 includes, for example, a photodiode PD, a transfer transistor TR, and a floating diffusion FD. The transfer transistor TR is electrically coupled to the photodiode PD. The floating diffusion FD temporarily holds charge transferred from the photodiode PD via the transfer transistor TR. The photodiode PD corresponds to one specific example of a “photoelectric converter” of the present disclosure. The floating diffusion FD corresponds to one specific example of a “charge accumulation section” of the present disclosure.

The photodiode PD performs photoelectric conversion to generate charge corresponding to the amount of received light. The cathode of the photodiode PD is electrically coupled to the source of the transfer transistor 1R, and the anode of the photodiode PD is electrically coupled to a reference electric potential line (for example, to the ground). The drain of the transfer transistor TR is electrically coupled to the floating diffusion FD, and the gate of the transfer transistor TR is electrically coupled to the pixel driving line 23 via coupling wiring lines 57 and 58 which will be described later. The transfer transistor TR is a CMOS (Complementary Metal Oxide Semiconductor) transistor, for example.

The floating diffusions FD of the respective sensor pixels 12 that share one reading circuit 22 are electrically coupled to each other, and are electrically coupled to the input end of the common reading circuit 22. The reading circuit 22 includes, for example, a reset transistor RST, a conversion transistor FDG, a selection transistor SEL, and an amplification transistor AMP. Note that the selection transistor SEL, the conversion transistor FDG, or both may be omitted on an as-needed basis.

The source of the conversion transistor FDG (the input end of the reading circuit 22) is electrically coupled to the floating diffusion FD via coupling wiring lines 54 and 65. The drain of the conversion transistor FDG is electrically coupled to the source of the reset transistor RST. The drain of the reset transistor RST is electrically coupled to a power supply line VDD and the drain of the amplification transistor AMP. The source of the amplification transistor AMP is electrically coupled to the drain of the selection transistor SEL. The gate of the amplification transistor AMP is electrically coupled to the source of the conversion transistor FDG via a coupling wiring line 55 and the coupling wiring line 65. The source of the selection transistor SEL (an output end of the reading circuit 22) is electrically coupled to the vertical signal line 24. The respective gates of the conversion transistor FDG, the reset transistor RST, and the selection transistor SEL are electrically coupled to the pixel driving line 23 (see FIG. 1).

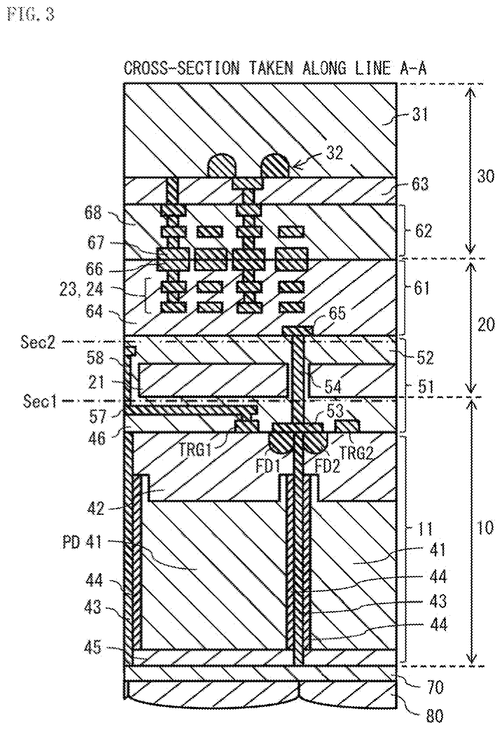

When the transfer transistor TR is turned on, the transfer transistor TR transfers the charge of the photodiode PD to the floating diffusion FD. The transfer transistor TR is, for example, of a planar type having a gate (transfer gate TRG) provided on a surface of the semiconductor substrate 11 as illustrated in FIG. 3 which will be described later. Note that the transfer transistor TR may be of a vertical type having a gate (vertical gate) extending from the surface of the semiconductor substrate 11 to a predetermined depth.

The conversion transistor FDG is used when conversion efficiency is switched. Typically, the pixel signal is low when an image is captured in a dark place. On the basis of Q=CV, as the capacitance of the floating diffusion FD (FD capacitance C) increases at the time of performing charge-voltage conversion, the V at the time of performing conversion into voltage at the amplification transistor AMP decreases. In contrast, in a bright place, the pixel signal increases. Thus, if the FD capacitance C is not large, the floating diffusion FD is not able to fully receive the charge of the photodiode PD. In addition, the FD capacitance C needs to be large so that the V at the time of performing conversion into a voltage at the amplification transistor AMP does not become excessively large (in other words, becomes small). On the basis of the above, when the conversion transistor FDG is turned on, the gate capacitance increases by the amount of the conversion transistor FDG, which leads to an increase in the FD capacitance C as a whole. In contrast, when the conversion transistor FDG is turned off, the FD capacitance C reduces as a whole. In this manner, switching ON and OFF of the conversion transistor FDG makes it possible to vary the FD capacitance C to switch the conversion efficiency.

The reset transistor RST resets an electric potential of the floating diffusion FD to a predetermined electric potential. When the reset transistor RST is turned on, the electric potential of the floating diffusion FD is reset to the electric potential of the power supply line VDD. The selection transistor SEL controls the timing at which the pixel signal is outputted from the reading circuit 22. The amplification transistor AMP generates, as a pixel signal, a signal of a voltage corresponding to the level of charge held at the floating diffusion FD. The amplification transistor AMP forms a source-follower type amplifier, and outputs a pixel signal having a voltage corresponding to the level of charge generated at the photodiode PD. Upon the selection transistor SEL being turned on, the amplification transistor AMP amplifies the electric potential of the floating diffusion FD, and outputs a voltage corresponding to the amplified electric potential to the column signal processing circuit 34 via the vertical signal line 24. The conversion transistor FDG, the reset transistor RST, the amplification transistor AMP, and the selection transistor SEL are, for example, CMOS transistors. The conversion transistor FDG, the reset transistor RST, the amplification transistor AMP, and the selection transistor SET are each, for example, of a planar type having a gate provided on a surface of the semiconductor substrate 21.

Note that the selection transistor SEL may be provided between the power supply line VDD and the amplification transistor AMP. In this case, the drain of the reset transistor RST is electrically coupled to the power supply line VDD and the drain of the selection transistor SEL. The source of the selection transistor SET is electrically coupled to the drain of the amplification transistor AMP. The gate of the selection transistor SEL is electrically coupled to the pixel driving line 23 (see FIG. 1). The source of the amplification transistor AMP (the output end of the reading circuit 22) is electrically coupled to the vertical signal line 24. The gate of the amplification transistor AMP is electrically coupled to the source of the reset transistor RST.

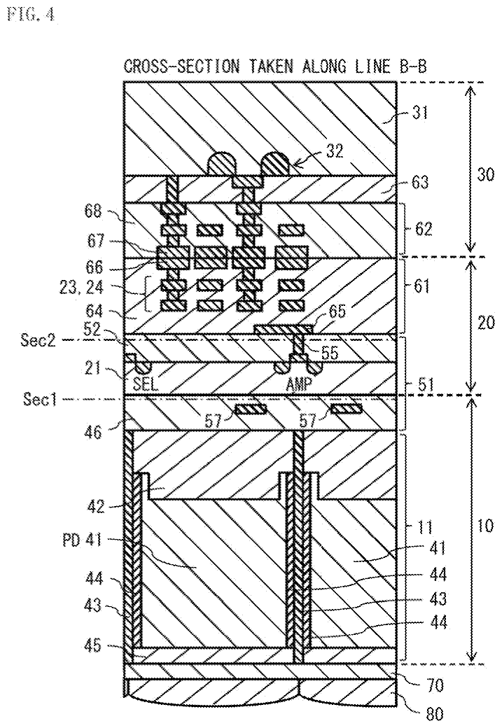

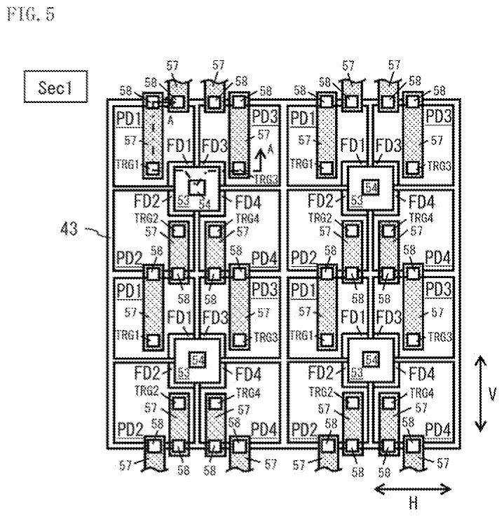

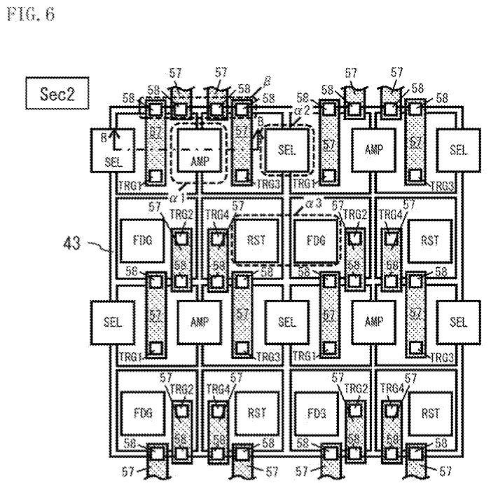

FIGS. 3 and 4 are each a diagram illustrating an example of the cross-sectional configuration, in the vertical direction, of the solid-state imaging device 1. FIGS. 3 and 4 each illustrate an example of the cross-sectional configuration at a portion, of the solid-state imaging device 1, that is opposed to the sensor pixel 12. FIG. 3 illustrates an example of the cross-sectional configuration at a portion corresponding to a line A-A in FIG. 5 which will be described later. FIG. 4 illustrates an example of the cross-sectional configuration at a portion corresponding to a line A-A in FIG. 6 which will be described later. FIGS. 5 and 6 are each a diagram illustrating an example of the cross-sectional configuration, in the horizontal direction, of the solid-state imaging device 1. FIG. 5 illustrates an example of the cross-sectional configuration at Sec1 in FIGS. 3 and 4. Note that, in FIG. 5, an insulating layer 46 is not illustrated, and the surface configuration of the semiconductor substrate 11 is illustrated in an overlapping manner. FIG. 6 illustrates an example of the cross-sectional configuration at Sec2 in FIGS. 3 and 4. Note that, in FIG. 6, an insulating layer 52 is not illustrated, and the surface configuration of the semiconductor substrate 21, the coupling wiring lines 57 and 58, the gate electrode TRG, and a device isolation section 43 in FIG. 5 are illustrated in an overlapping manner.

The solid-state imaging device 1 is configured such that the first substrate 10, the second substrate 20, and the third substrate 30 are stacked in this order. In addition, the solid-state imaging device 1 includes a color filter 70 and a light receiving lens 80 on a rear surface side (light entering surface side) of the first substrate 10. The color filter 70 and the light receiving lens 80 are each provided, for example, for each of the sensor pixels 12. In other words, the solid-state imaging device 1 is a back-illuminated imaging unit.

The first substrate 10 is configured such that the insulating layer 46 is stacked on the semiconductor substrate 11. The insulating layer 46 corresponds to one specific example of an “insulating layer” of the present disclosure. The insulating layer 46 includes, for example, an inorganic insulating material such as SiO₂ or SiN. The first substrate 10 includes the insulating layer 46 as a portion of a wiring layer 51 which will be described later. The insulating layer 46 is provided in a space between the semiconductor substrate 11 and the semiconductor substrate 21. In other words, the semiconductor substrate 21 is stacked on the semiconductor substrate 11 with the insulating layer 46 being interposed therebetween. The semiconductor substrate 11 includes a silicon substrate. For example, the semiconductor substrate 11 includes a p-well layer 42 at a portion of the surface and in the vicinity thereof, and includes a PD 41 of an electrically conductive type differing from that of the p-well layer 42 in a region (region deeper than the p-well layer 42) other than that. The p-well layer 42 includes a p-type semiconductor region. The PD 41 includes a semiconductor region of an electrically conductive type (specifically, an n-type) differing from that of the p-well layer 42. The semiconductor substrate 11 includes, within the p-well layer 42, the floating diffusion FD as a semiconductor region of an electrically conductive type (specifically, an n-type) differing from that of the p-well layer 42.

The first substrate 10 (semiconductor substrate 11) includes the photodiode PD, the transfer transistor TR, and the floating diffusion FD for each of the sensor pixels 12. The first substrate 10 is configured such that the transfer transistor TR and the floating diffusion FD are provided at a portion, on the front surface side (a side that is opposite from the light entering surface side, or the second substrate 20 side), of the semiconductor substrate 11. The first substrate 10 (semiconductor substrate 11) includes the device isolation section 43 that isolates the individual sensor pixels 12. The device isolation section 43 is provided to extend in a direction (direction perpendicular to the surface of the semiconductor substrate 11) of the normal to the semiconductor substrate 11. The device isolation section 43 is provided between two sensor pixels 12 that are adjacent to each other. The device isolation section 43 electrically isolates the sensor pixels 12 that are adjacent to each other. The device isolation section 43 includes, for example, silicon oxide. For example, the device isolation section 43 penetrates through the semiconductor substrate 11.

The first substrate 10 further includes, for example, a p-well layer 44 that is on a side surface of the device isolation section 43 and is in contact with a surface on a photodiode PD side. The p-well layer 44 includes a semiconductor region of an electrical conductivity type (specifically, p-type) differing from that of the photodiode PD. The first substrate 10 further includes, for example, a fixed charge film 45 in contact with the rear surface of the semiconductor substrate 11. The fixed charge film 45 is negatively charged in order to suppress occurrence of a dark current due to an interface state on the light receiving surface side of the semiconductor substrate 11. The fixed charge film 45 includes, for example, an insulating film having a negative fixed charge. The material of such an insulating film is, for example, hafnium oxide, zirconium oxide, aluminum oxide, titanium oxide, or tantalum oxide. With an electric field induced by the fixed charge film 45, a hole accumulation layer is formed at an interface of the semiconductor substrate 11 on the light receiving surface side. This hole accumulation layer suppresses generation of electrons from the interface. The color filter 70 is provided on the rear surface side of the semiconductor substrate 11. The color filter 70 is provided, for example, so as to be in contact with the fixed charge film 45, and is provided at a position that is opposed to the sensor pixel 12 with the fixed charge film 45 being interposed therebetween. The light receiving lens 80 is provided, for example, so as to be in contact with the color filter 70, and is provided at a position that is opposed to the sensor pixel 12 with the color filter 70 and the fixed charge film 45 being interposed therebetween.

The second substrate 20 is configured such that the insulating layer 52 is stacked on the semiconductor substrate 21. The insulating layer 52 includes, for example, an inorganic insulating material such as Sift or SiN. The second substrate 20 includes the insulating layer 52 as a portion of the wiring layer 51. The insulating layer 52 is provided in a space between the semiconductor substrate 21 and the semiconductor substrate 31. The semiconductor substrate 21 includes a silicon substrate. The second substrate 20 (semiconductor substrate 21) includes one reading circuit 22 for each unit of four sensor pixels 12, for example. The second substrate 20 is configured such that the reading circuit 22 is provided at a portion of the semiconductor substrate 21 on the front surface side (third substrate 30 side). The second substrate 20 is bonded to the first substrate 10 with the rear surface of the semiconductor substrate 21 being directed toward the front surface side of the semiconductor substrate 11. The semiconductor substrate 21 has multiple openings that run through the semiconductor substrate 21. The insulating layer 52 is embedded in each of the openings provided in the semiconductor substrate 21, and, for example, a coupling wiring line 54 or 58 which will be described later or the like runs through each of the openings.

The stacked body including the first substrate 10 and the second substrate 20 includes the wiring layer 51. The wiring layer 51 includes a coupling section 53, and the coupling wiring lines 54 and 55 for each unit of multiple sensor pixels 12 that share the reading circuit 22. The coupling section 3 and the coupling wiring lines 54 and 55 each include, for example, an electrically conductive material such as polysilicon, tungsten, or copper. A portion of the coupling section 53 and a portion of the coupling wiring line 54 are provided within the insulating layer 46 of the wiring layer 51. A portion of the coupling wiring line 54, and the coupling wiring line 55 are provided within the insulating layer 52 of the wiring layer 51.

The coupling section 53 is electrically coupled to the floating diffusion FD of each of the multiple sensor pixels 12 that share the reading circuit 22. The four floating diffusions FD of the respective four sensor pixels 12 that share the reading circuit 22 are disposed close to each other with the device isolation section 43 being interposed therebetween. Thus, the four floating diffusions FD are electrically coupled to each other by one coupling section 53.

The coupling wiring line 54 is provided so as to run through the opening of the semiconductor substrate 21, and extends in the direction of the normal to the semiconductor substrate 21. The coupling wiring line 54 has one end coupled to the coupling section 53. The coupling wiring line 54 has another end coupled to the coupling wiring line 65 within a wiring layer 61 that will be described later. The first substrate 10 and the second substrate 20 are electrically coupled to each other by the coupling section 53 and the coupling wiring lines 54 and 55. The coupling wiring line 65 is coupled to the gate of the amplification transistor AMP and the source of the conversion transistor FDG. The coupling wiring line 55 is formed so as to penetrate through the insulating layer 52, and extends in the direction of the normal to the insulating layer 52. The coupling wiring line 55 has one end coupled to the gate of the amplification transistor AMP. The coupling wiring line 55 has another end coupled to the coupling wiring line 65.

The wiring layer 51 further includes, for each of the sensor pixels 12, the coupling wiring line 57 coupled to the gate (transfer gate TRG) of the transfer transistor TR, and the coupling wiring line 58 coupled to the coupling wiring line 57. The coupling wiring line 57 corresponds to one specific example of a “gate wiring line” of the present disclosure. The coupling wiring line 57 extends in a predetermined direction (first direction V) as illustrated in FIGS. 5 and 6, for example. The coupling wiring lines 57 each include, for example, an electrically conductive material such as polysilicon, tungsten, or copper. The coupling wiring line 58 is formed so as to run through the opening of the semiconductor substrate 21, and extends in the direction of the normal to the semiconductor substrate 21. The coupling wiring line 58 has one end coupled to the coupling wiring line 57. The coupling wiring line 58 has another end electrically coupled to the pixel driving line 23 via a wiring line within the insulating layer 52. The coupling wiring lines 58 each include, for example, an electrically conductive material such as polysilicon, tungsten, or copper.

The coupling wiring line 58 is provided, for example, in a region (directly above the device isolation section 43) that is opposed to the device isolation section 43. The coupling wiring line 58 is provided, for example, at a portion of the device isolation section 43, that forms the outer edge of the multiple sensor pixels 12 that share the reading circuit 22. For example, pay attention to four sensor pixels 12 (four sensor pixels 12 included in a first imaging pixel) that share a reading circuit 22 and also to four sensor pixels 12 included in a second imaging pixel disposed adjacent to the first imaging pixel in a second direction H. The second direction H is a direction perpendicular to the first direction V. In this case, in a region (hereinafter, referred to as a “region β” (see FIG. 6)), of the device isolation section 43, that is opposed to a portion where the first imaging pixel and the second imaging pixel are separated from each other, there is provided the coupling wiring line 58 of each of the four sensor pixels 12 that are in contact with the region β. In other words, in the region A, four coupling wiring lines 58 are disposed side by side in the second direction H perpendicular to the first direction V.

In addition, pay attention to the region α1 illustrated in FIG. 6, for example. The region α1 is a region between a coupling wiring line 57 (first gate wiring line) of one sensor pixel 12 of two particular sensor pixels 12 and a coupling wiring line 57 (second gate wiring line) of another sensor pixel 12 thereof. The two particular sensor pixels 12 are two sensor pixels 12 disposed side by side in the second direction H among four sensor pixels 12 that share a reading circuit 22. In this case, the amplification transistor AMP is disposed in the region α1 in plan view.

Furthermore, pay attention to a region α2 illustrated in FIG. 6, for example. The region α2 is a region between a coupling wiring line 57 (first gate wiring line) of one sensor pixel 12 among two sensor pixels 12 disposed side by side in the second direction H and a coupling wiring line 57 (second gate wiring line) of another sensor pixel 12 thereof. In this case, the selection transistor SET is disposed in the region α2 in plan view.

In addition, pay attention to a region α3 illustrated in FIG. 6, for example. The region α3 is a region between a coupling wiring line 57 (first gate wiring line) of one sensor pixel 12 among two sensor pixels 12 disposed side by side in the second direction H and a coupling wiring line 57 (second gate wiring line) of another sensor pixel 12 thereof. In this case, the reset transistor RST and the conversion transistor FDG are disposed in the region α3 in plan view.

The second substrate 20 further includes the wiring layer 61 that is in contact with the wiring layer 51 (insulating layer 52). The wiring layer 61 is also in contact with the surface, on the second substrate 20 side, of the third substrate 30. The wiring layer 61 includes, for example, an insulating layer 64 and various wiring lines (for example, the multiple pixel driving lines 23, the multiple vertical signal lines 24, and the multiple coupling wiring lines 65) provided within the insulating layer 64. The pixel driving lines 23, the vertical signal lines 24, and the coupling wiring lines 65 each include, for example, an electrically conductive material such as polysilicon, tungsten, or copper.

The wiring layer 61 further includes, for example, multiple pad electrodes 66 within the insulating layer 64. Each of the pad electrodes 66 includes, for example, metal such as Cu (copper) or Al (aluminum). Each of the pad electrodes 66 is exposed at a surface of the wiring layer 61. Each of the pad electrodes 66 is used to electrically couple the second substrate 20 and the third substrate 30, and to bond the second substrate 20 and the third substrate 30 to each other. Each of the multiple pad electrodes 66 is provided, for example, for each of the pixel driving lines 23 and the vertical signal lines 24.

The third substrate 30 is configured, for example, such that the wiring layer 63 is stacked on the semiconductor substrate 31. Note that the surface of the front surface side of the third substrate 30 and the surface of the front surface side of the second substrate 20 are bonded to each other. Thus, in the description of the configuration within the third substrate 30, explanation concerning upward and downward is opposite to the upward and downward directions in the drawings. The semiconductor substrate 31 includes a silicon substrate. The third substrate 30 is configured such that the logic circuit 32 is provided at a portion of the semiconductor substrate 31 on the front surface side. The third substrate 30 further includes, for example, the wiring layer 62 on the wiring layer 63. The wiring layer 62 includes, for example, an insulating layer 68 and multiple pad electrodes 67 provided within the insulating layer 68. The multiple pad electrodes 67 are electrically coupled to the logic circuit 32. The pad electrodes 67 each include, for example, metal such as Cu (copper) or Al (aluminum). Each of the pad electrodes 67 is exposed at the surface of the wiring layer 62. Each of the pad electrodes 67 is used to electrically couple the second substrate 20 and the third substrate 30, and to bond the second substrate 20 and the third substrate 30 to each other. In addition, the number of the pad electrodes 67 is not necessarily two or more, and even one pad electrode 67 is able to be electrically coupled to the logic circuit 32. The second substrate 20 and the third substrate 30 are electrically coupled to each other through joining of the pad electrodes 66 and 67 to each other. The gate (transfer gate TG) of the transfer transistor TR is electrically coupled to the logic circuit 32 via the coupling wiring line 58 and the pad electrodes 66 and 67. The third substrate 30 is bonded to the second substrate 20 with the front surface of the semiconductor substrate 31 being directed toward the front surface side of the semiconductor substrate 21.

As illustrated in FIGS. 3 and 4, the first substrate 10 and the second substrate 20 are electrically coupled to each other by the coupling wiring lines 54 and 58. In addition, as illustrated in FIGS. 3 and 4, the second substrate 20 and the third substrate 30 are electrically coupled to each other through joining of the pad electrodes 66 and 67 to each other. Here, the reading circuit 22 is formed in the second substrate 20, and the logic circuit 32 is formed in the third substrate 30. This makes it possible to increase the freedom of layout in terms of arrangement, the number of contacts for coupling, or the like in providing the structure for electrically coupling the second substrate 20 and the third substrate 30 to each other, as compared with a structure for electrically coupling the first substrate 10 and the second substrate 20 to each other. It is thus possible to employ joining of pad electrodes 66 and 67 to each other, as the structure for electrically coupling the second substrate 20 and the third substrate 30 to each other.

### [Manufacturing Method]

Next, a method of manufacturing the solid-state imaging device 1 will be described.

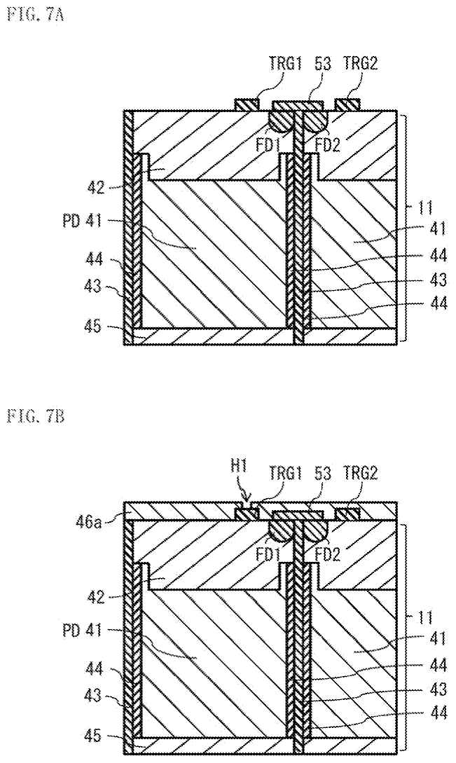

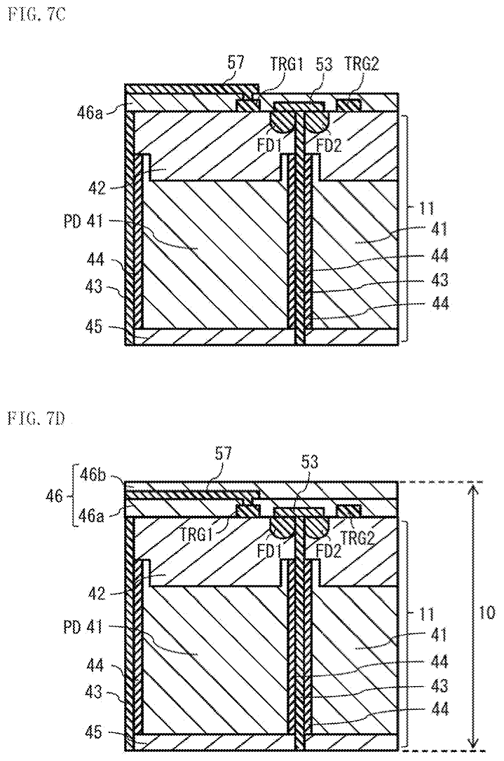

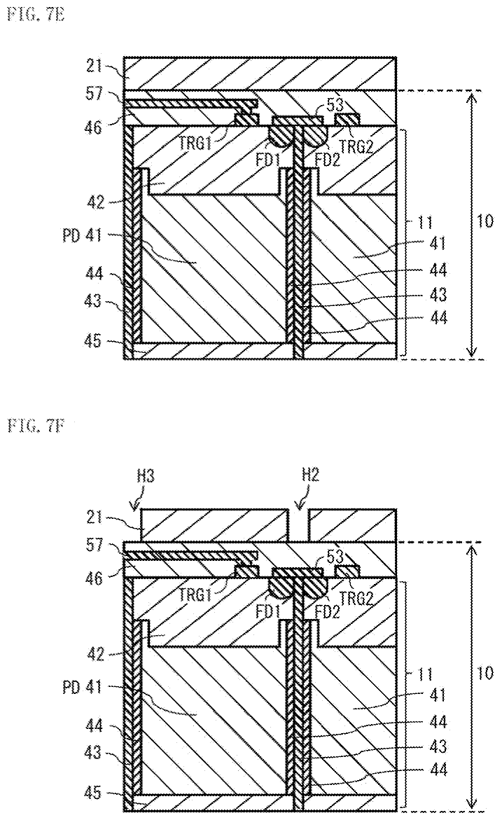

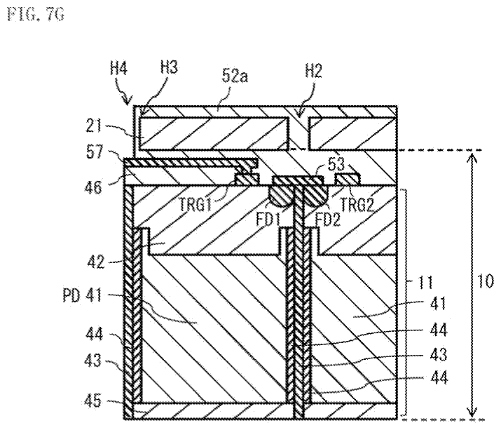

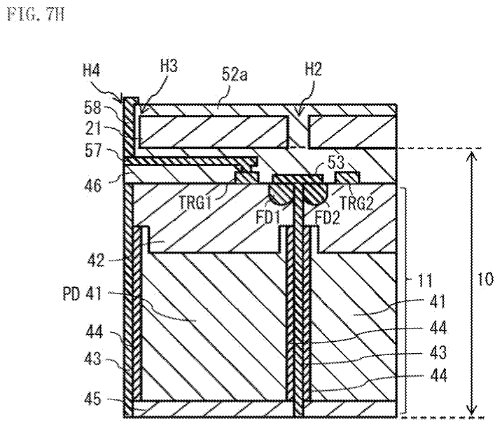

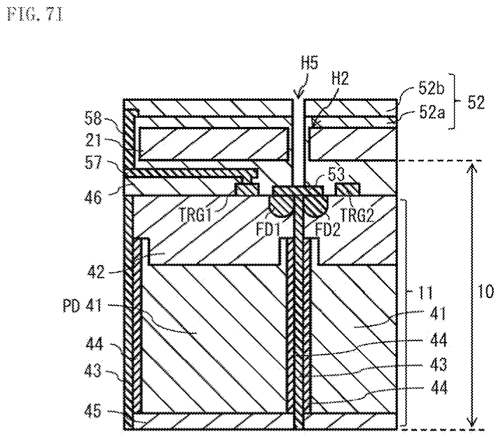

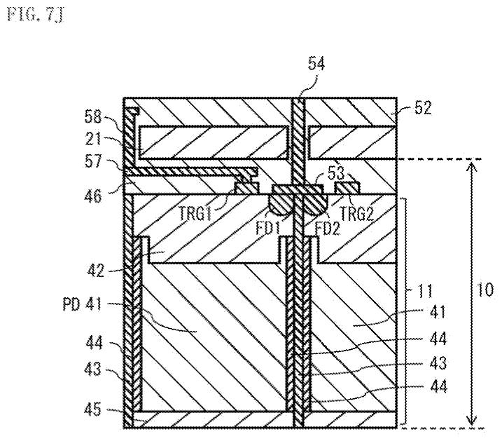

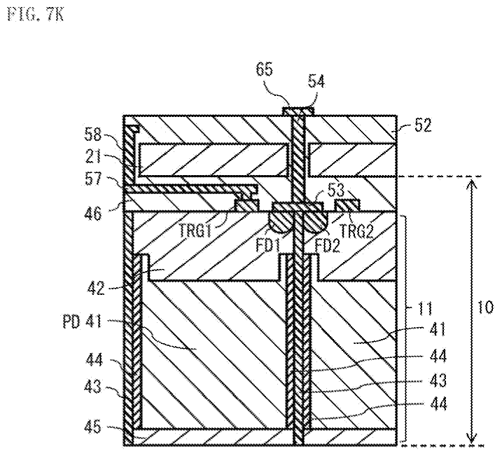

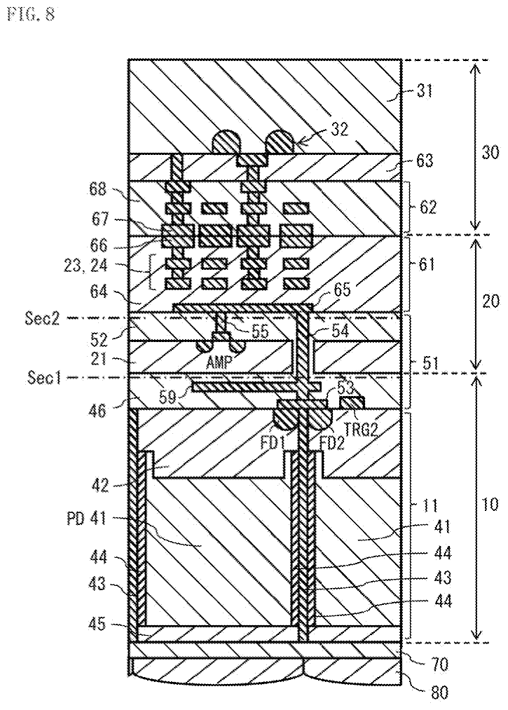

First, the p-well layer 42, the device isolation section 43, and the p-well layer 44 are formed in the semiconductor substrate 11. Thereafter, the photodiode PD, the transfer transistor TR (transfer gate TRG), and the floating diffusion FD are formed in the semiconductor substrate 11 (FIG. 7A). The sensor pixel 12 is thereby formed in the semiconductor substrate 11. Thereafter, an insulating layer 46a is formed on the semiconductor substrate 11 (FIG. 7B). At this time, of the insulating layer 46a, an opening H1 from which the surface of the insulating layer 46a is exposed is formed directly above the insulating layer 46a.

Thereafter, the coupling wiring line 57 is formed with respect to the surface of the insulating layer 46a having the opening H1 (FIG. 7C). Thereafter, an insulating layer 46b is formed such that the coupling wiring line 57 is embedded therein (FIG. 7D). The insulating layer 46 is thereby formed on the semiconductor substrate 11. Thereafter, the semiconductor substrate 21 where the reading circuit 22 is formed is placed on the surface of the insulating layer 46 (FIG. 7E). Thereafter, opening H2 and H3 are provided at predetermined locations of the semiconductor substrate 21 (FIG. 7F). Thereafter, an insulating layer 52a is formed with respect to a surface having the opening H2 and H3. Thereafter, an opening H4 running through the opening H3 is provided at a portion of the insulating layer 52a filling the opening H3 (FIG. 7G). The coupling wiring line 57 is exposed at a bottom surface of the opening H4.

Thereafter, the coupling wiring line 58 is formed such that the opening H4 (FIG. 7H) is filled. Thereafter, an insulating layer 52b is formed with respect to a surface including the coupling wiring line 58. The insulating layer 52 is thereby formed on the semiconductor substrate 21. Thereafter, an opening H5 running through the opening H2 is provided at a portion of the insulating layer 52 filling the opening H2 (FIG. 7I). The coupling section 53 is exposed at a bottom surface of the opening H5. Thereafter, the coupling wiring line 54 is formed such that the opening H5 is filled (FIG. 7J). Thereafter, the coupling wiring line 65 that is in contact with the coupling wiring line 54 is formed on a surface of the insulating layer 52 (FIG. 7K). Thereafter, the wiring layer 61 is formed, and the third substrate 30 is bonded on the wiring layer 61. In this manner, the solid-state imaging device 1 is manufactured.

### [Effects]

Next, effects of the solid-state imaging device 1 according to the present embodiment will be described.

Typically, in a solid-state imaging device having a two-dimensional structure, the area of one pixel has been reduced by introducing a miniaturization process and improving mounting density. In recent years, a solid-state imaging device having a three-dimensional structure has been developed in order to further miniaturize the solid-state imaging device and increase density of pixels. In the solid-state imaging device having a three-dimensional structure, for example, a semiconductor substrate including multiple photoelectric converters and a semiconductor substrate including an amplification transistor are stacked on each other. The amplification transistor generates a signal having a voltage corresponding to a level of charge obtained at each of the photoelectric converters (see, for example, PTL 1). Incidentally, in a case of an existing solid-state imaging device, as density of pixels increases, signals within pixels can interfere with each other, possibly leading to a deterioration in a noise characteristic. Such a problem is not limited to the solid-state imaging device but also can occur in a photoelectric conversion device in general.

In contrast, in the present embodiment, one transistor (pixel transistor) that forms the reading circuit 22 is disposed, in plan view, in a region (for example, the region α1, α2, or α3) between two coupling wiring lines 57 (the first gate wiring line and the second gate wiring line) adjacent to each other. This makes it possible to reduce a possibility that a signal applied to the coupling wiring line 57 interferes with the pixel transistor, for example, as compared with a case where the coupling wiring line 57 is disposed directly below the pixel transistor. As a result, it is possible to suppress a deterioration in the noise characteristic of the pixel transistor.

In addition, in the present embodiment, the amplification transistor AMP is provided in a region, of the device isolation section 43, that is opposed to a portion where two sensor pixels 12 adjacent to each other are separated from each other. This makes it possible to secure a sufficient space for providing the reading circuit 22 in the semiconductor substrate 21.

In addition, in the present embodiment, two coupling wiring lines 57 (the first gate wiring line and the second gate wiring line) adjacent to each other extend in the first direction V intersecting the second direction H in which they are opposed to each other with the amplification transistor AMP being interposed therebetween. This makes it possible to reduce the possibility that a signal applied to the coupling wiring line 57 interferes with the amplification transistor AMP, for example, as compared with a case where the coupling wiring line 57 is disposed directly below the amplification transistor AMP. As a result, it is possible to suppress a deterioration in the noise characteristic of the amplification transistor AMP.

### 2. Modification Examples

In the following, modification examples of the solid-state imaging device 1 according to the embodiment described above will be described.

### Modification Example A

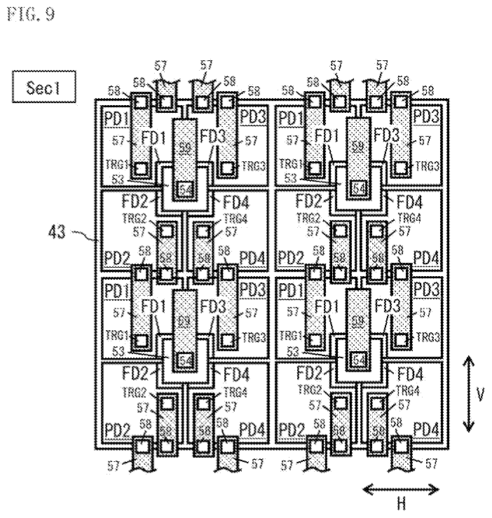

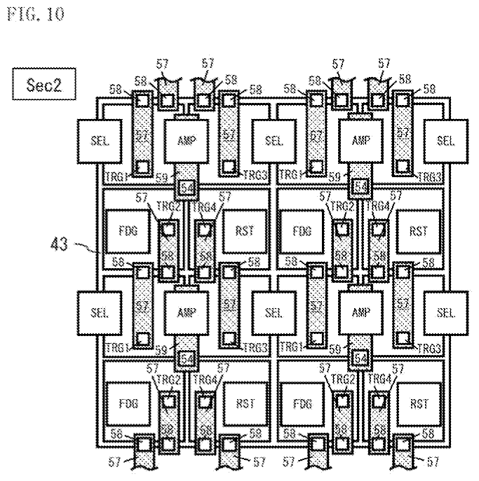

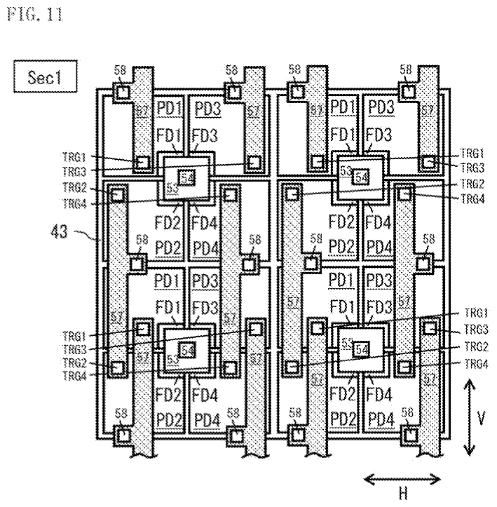

In the embodiment described above, a conductive layer 59 as illustrated in FIGS. 8, 9, and 10 may be provided within the insulating layer 46 of the wiring layer 51, for example. Note that FIG. 9 illustrates an example of a horizontal cross-sectional configuration at a portion corresponding to Sec1 in FIG. 8. FIG. 10 illustrates an example of a horizontal cross-sectional configuration at a portion corresponding to Sec2 in FIG. 8. The conductive layer 59 is provided in a region that is opposed to the amplification transistor AMP (in particular, a channel region of the amplification transistor AMP). Regarding the amplification transistor AMP, this makes it possible to reduce a possibility that a signal from the semiconductor substrate 11 side interferes with the amplification transistor AMP. As a result, it is possible to suppress a deterioration in the noise characteristic of the amplification transistor AMP.

In addition, in the present modification example, the conductive layer 59 may be coupled to the coupling wiring line 54, for example, as illustrated in FIG. 8. In a case of such a configuration, it is possible to control an electric potential of the conductive layer 59 through the coupling wiring line 54. For example, an electric potential of the coupling wiring line 54 may be an electric potential of the power supply line VDD, or may be the ground potential.

### Modification Example B

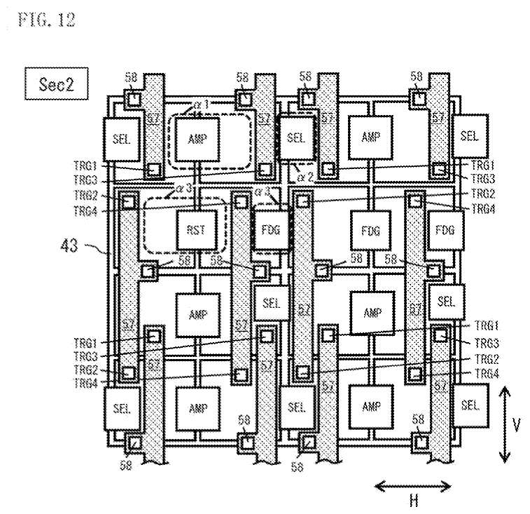

Pay attention to one coupling wiring line 57 (first gate wiring line) of two coupling wiring lines 57 adjacent to each other in the second direction H. In this case, in the embodiment described above and the modification examples thereof, the first gate wiring line may be coupled to the gate (transfer gate TRG) of the transfer transistor TG of each of the multiple sensor pixels 12 including a sensor pixel 12 to which the first gate wiring line is coupled, as illustrated in FIGS. 11 and 12, for example. In addition, pay attention to another coupling wiring line 57 (second gate wiring line) of the two coupling wiring lines 57 adjacent to each other in the second direction H. In this case, in the embodiment described above and the modification examples thereof, the second gate wiring line may be coupled to the gate (transfer gate TRG) of the transfer transistor TG of each of the multiple sensor pixels 12 including a sensor pixel 12 to which the second gate wiring line is coupled, as illustrated in FIGS. 11 and 12, for example. This makes it possible to reduce the number of vertical wiring lines (coupling wiring lines 58) that electrically couple the first substrate 10 and the second substrate 20 to each other, as compared with the embodiment described above and the modification examples thereof. As a result, it is possible to secure a sufficient space for forming the reading circuit 22 in the semiconductor substrate 21.

### Modification Example C

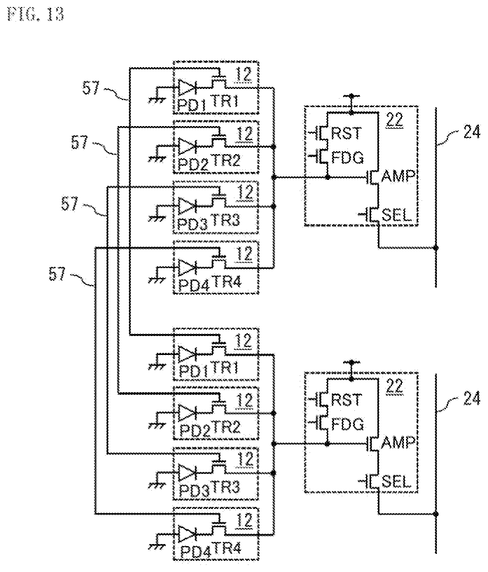

The gate of the transfer transistor TR of a sensor pixel 12 included in one imaging pixel of two imaging pixels adjacent to each other is referred to as a “first gate,” and the gate of the transfer transistor TR of a sensor pixel 12 included in another imaging pixel thereof is referred to as a “second gate.” In this case, in the embodiment described above and the modification examples thereof, the coupling wiring line 57 may be configured to couple the first gate and the second gate to each other as illustrated in FIG. 13, for example. In a case of such a configuration, it is possible to reduce the number of the coupling wiring lines 57, as compared with a case where one coupling wiring line 57 is provided for each of the sensor pixels 12. As a result, it is possible to secure a sufficient space for providing the reading circuit 22 in the semiconductor substrate 21.

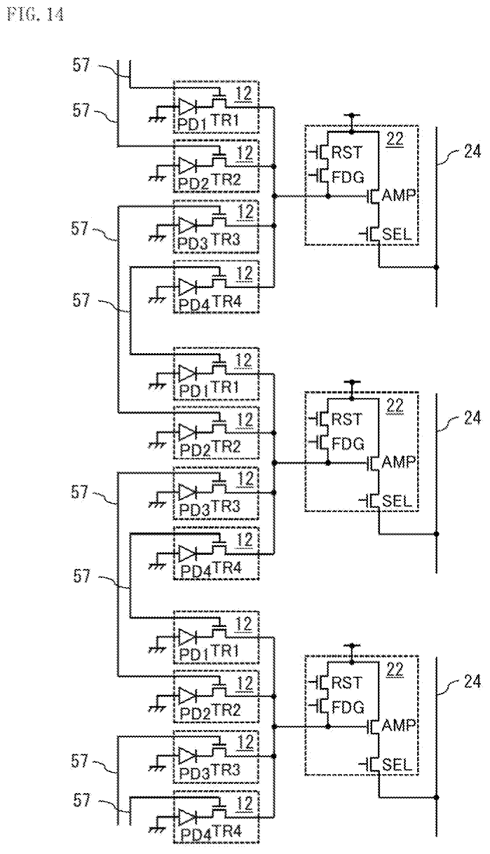

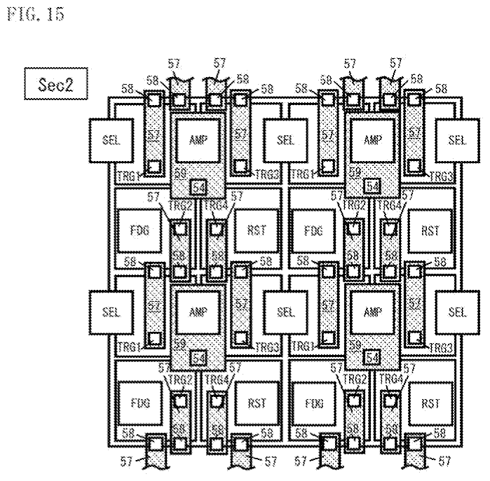

The gates of the transfer transistors TR of two sensor pixels 12 included in one imaging pixel of two imaging pixels adjacent to each other are each referred to as a “third gate,” and the gates of the transfer transistors TR of two sensor pixels 12 included in another imaging pixel thereof are each referred to as a “fourth gate”. In this case, the embodiment described above and the modification examples thereof may be configured such that two coupling wiring lines 57 couple two third gates and two fourth gates to each other as illustrated in FIG. 14, for example. In a case of such a configuration, it is possible to reduce the number of the coupling wiring lines 57, as compared with the case where one coupling wiring line 57 is provided for each of the sensor pixels 12. As a result, it is possible to secure a sufficient space for providing the reading circuit 22 in the semiconductor substrate 21.

### Modification Example D

In the modification example D described above, the conductive layer 59 may be provided in a region that is opposed to the entire amplification transistor AMP as illustrated in FIG. 15, for example. In a case of such a configuration, the possibility that a signal from the semiconductor substrate 11 side interferes with the amplification transistor AMP is further reduced. As a result, it is possible to further suppress a deterioration in the noise characteristic of the amplification transistor AMP.

### Modification Example E

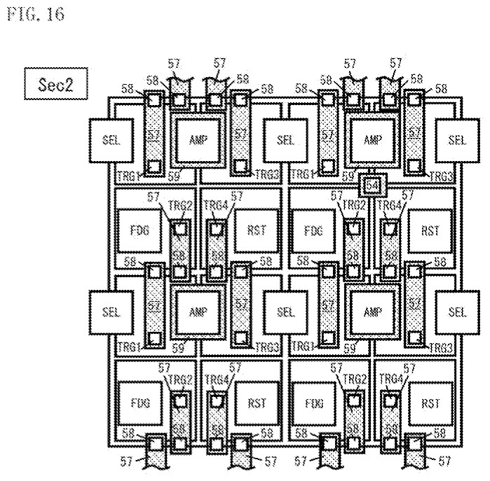

In the modification example D described above, the conductive layer 59 may be insulated and isolated from other conductive bodies such as the coupling wiring line 54 as illustrated in FIG. 16, for example. In this case, the conductive layer 59 may be floating. In such a case also, the possibility that a signal from the semiconductor substrate 11 side interferes with the amplification transistor AMP is reduced. As a result, it is possible to suppress a deterioration in the noise characteristic of the amplification transistor AMP.

### Modification Example E

In the embodiment described above and the modification examples thereof, one reading circuit 22 may be coupled only to one sensor pixel 12 as illustrated in FIG. 17, for example. In a case of such a configuration also, the possibility that a signal applied to the coupling wiring line 57 interferes with the pixel transistor is reduced, as with the embodiment described above and the modification examples thereof. As a result, it is possible to suppress a deterioration in the noise characteristic of the pixel transistor.

### Modification Example F

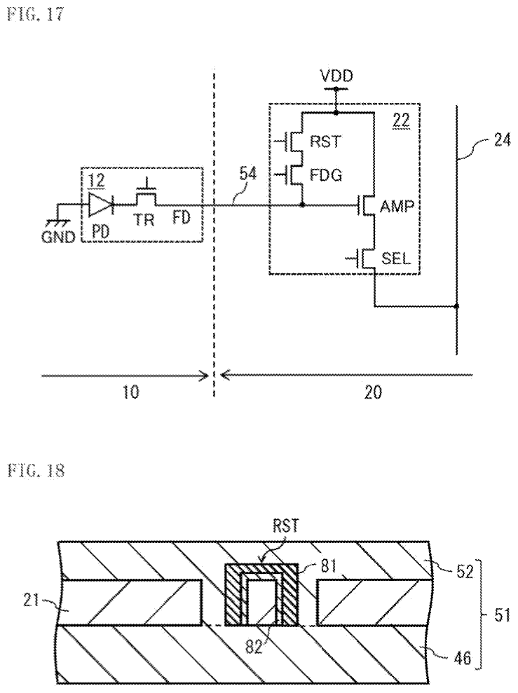

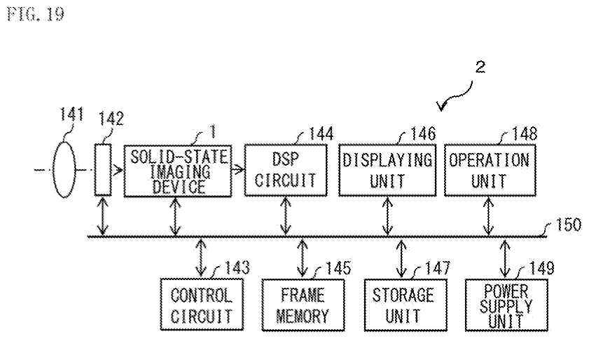

In the embodiment described above and the modification examples thereof, the amplification transistor AMP may be configured as a FinFET. The amplification transistor AMP includes a channel region, a source region, and a drain region within an inner side surface of an opening provided by performing selective etching on the semiconductor substrate 21 as illustrated in FIG. 18, for example. In other words, the amplification transistor AMP includes the channel region, the source region, and the drain region within a surface intersecting the surface of the semiconductor substrate 21. The amplification transistor AMP further includes a gate insulating film 82 that is in contact with the channel region, and also includes a gate electrode 81 that is opposed to the channel region with the gate insulating film 82 being interposed therebetween. In a case where the amplification transistor AMP is configured as a FinFET also, the possibility that a signal applied to the coupling wiring line 57 interferes with the pixel transistor is reduced, as with the embodiment described above and the modification examples thereof. As a result, it is possible to suppress a deterioration in the noise characteristic of the pixel transistor.

### 3. Application Examples

FIG. 19 is a diagram illustrating an example of a schematic configuration of an imaging system 2 including the solid-state imaging device 1 according to the embodiment described above and the modification examples thereof.

The imaging system 2 is, for example, an electronic apparatus such as: an imaging apparatus such as a digital still camera or a video camera; or a mobile terminal apparatus such as a smartphone or a tablet-type terminal. The imaging system 2 includes, for example, the solid-state imaging device 1 according to the embodiment described above and the modification examples thereof, an optical system 141, a shutter device 142, a control circuit 143, a DSP circuit 144, a frame memory 145, a displaying unit 146, a storage unit 147, an operation unit 148, and a power supply unit 149. In the imaging system 2, the solid-state imaging device 1 according to the embodiment described above and the modification examples thereof, the DSP circuit 144, the frame memory 145, the displaying unit 146, the storage unit 147, the operation unit 148, and the power supply unit 149 are coupled to each other via a bus line 150.

The optical system 141 is configured to include one or multiple lenses, and guides light (incident light) from a subject to the solid-state imaging device 1 to form an image on a light receiving surface of the solid-state imaging device 1. The shutter device 142 is disposed between the optical system 141 and the solid-state imaging device 1, and controls a light emitting period and a light shielding period for the solid-state imaging device 1 under a control by the control circuit 143. The solid-state imaging device 1 accumulates signal charge for a certain period of time in accordance with light of the image formed on the light receiving surface through the optical system 141 and the shutter device 142. The signal charge accumulated at the solid-state imaging device 1 is transferred, as a pixel signal (image data), to the DSP circuit 144 in accordance with a drive signal (timing signal) supplied from the control circuit 143. In other words, the solid-state imaging device 1 receives image light (incident light) incident through the optical system 141 and the shutter device 142, and outputs the pixel signal corresponding to the received image light (incident light) to the DSP circuit 144. The control circuit 143 outputs a drive signal used to control a transfer operation of the solid-state imaging device 1 and a shutter operation of the shutter device 142 to drive the solid-state imaging device 1 and the shutter device 142.

The DSP circuit 144 is a signal processing circuit that processes the pixel signal (image data) outputted from the solid-state imaging device 1. The frame memory 145 temporarily holds image data processed by the DSP circuit 144, on a frame basis. The displaying unit 146 includes, for example, a panel-type display such as a liquid crystal panel or an organic EL (Electro Luminescence) panel, and displays a moving image or a still image captured by the solid-state imaging device 1. The storage unit 147 records image data related to a moving image or a still image captured by the solid-state imaging device 1, in a recording medium such as a semiconductor memory or a hard disk. In accordance with an operation by a user, the operation unit 148 outputs an operation instruction regarding various functions that the imaging system 2 has. The power supply unit 149 supplies, on an as-needed basis, various types of power supply serving as operation power supply of the solid-state imaging device 1, the DSP circuit 144, the frame memory 145, the displaying unit 146, the storage unit 147, and the operation unit 148, to these targets of supply.

In the present application example, the solid-state imaging device 1 according to the embodiment described above and the modification examples thereof is applied to the imaging system 2. This makes it possible to reduce the size of or increase the resolution of the solid-state imaging device 1, making it possible to provide the imaging system 2 having a reduced size or a high resolution.

### 4. Practical Application Examples

### Application Examples 1

The technology (present technology) according to the present disclosure is applicable to various products. For example, the technology according to the present disclosure may be achieved as an apparatus to be mounted on a mobile body of any kind of an automobile, an electric automobile, a hybrid electric automobile, a motorcycle, a bicycle, a personal mobility, an airplane, a drone, a vessel, a robot, and the like.

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile body control system to which the technology according to the present disclosure is applicable has been described above. Of the configurations described above, the technology according to the present disclosure is applicable to the imaging section 12031. Specifically, the solid-state imaging device 1 according to the embodiment described above and the modification examples thereof is applicable to the imaging section 12031. Applying the technology according to the present disclosure to the imaging section 12031 makes it possible to suppress a reduction in efficiency conversion of the imaging section 12031. It is thus possible to provide a mobile body control system having high image quality.

### Practical Application Example 2

FIG. 22 is a view depicting an example of a schematic configuration of an endoscopic surgery system to which the technology according to an embodiment of the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 23 is a block diagram depicting an example of a functional configuration of the camera head 11102 and the CCU 11201 depicted in FIG. 22.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure is applicable has been described. Of the configurations described above, the technology according to the present disclosure is favorably applicable to the image pickup unit 11402 provided at the camera head 11102 of the endoscope 11100. Applying the technology according to the present disclosure to the image pickup unit 11402 makes it possible to suppress a reduction in efficiency conversion of the image pickup unit 11402. It is thus possible to provide the endoscope 11100 having high image quality.

The present disclosure has been described above with reference to the embodiment, the modification examples thereof, the application examples, and the practical application examples. However, the present disclosure is not limited to the embodiment and the like described above, and various modifications may be made. Note that the effects described herein are merely examples. The effects of the present disclosure are not limited to the effects described herein. The present disclosure may have any effect other than the effects described herein.

The present disclosure is not limited, for example, to the imaging device, and is applicable, for example, to a semiconductor device. For example, the components of the solid-state imaging device 1 according to the embodiment described above and the modification examples thereof are applicable to the semiconductor device.

In addition, the present disclosure may employ the following configurations.

(1)

A photoelectric conversion device including:
a first semiconductor layer in which a photoelectric converter, a charge accumulation section, and a transfer transistor are provided for each of pixels, the charge accumulation section accumulating signal charge generated at the photoelectric converter, the transfer transistor transferring the signal charge from the photoelectric converter to the charge accumulation section;
a second semiconductor layer in which a pixel transistor is provided for each unit of one or more of the pixels, the pixel transistor reading out the signal charge from the charge accumulation section, the second semiconductor layer being stacked on the first semiconductor layer; and
a wiring layer that is provided between the first semiconductor layer and the second semiconductor layer and in which a gate wiring line coupled to a gate of the transfer transistor is provided within an insulating layer for each of the pixels, in which
the pixel transistor is disposed, in plan view, in a region between a first gate wiring line and a second gate wiring line in a first pixel and a second pixel being two of the pixels and being adjacent to each other, the first gate wiring line being coupled to the gate of the transfer transistor included in the first pixel, the second gate wiring line coupled to the gate of the transfer transistor included in the second pixel.
   (2)

The photoelectric conversion device according to (1), in which the pixel transistor includes at least one of an amplification transistor, a reset transistor, a selection transistor, or a conversion transistor, the amplification transistor generating a signal voltage corresponding to a level of the signal charge, the reset transistor resetting an electric potential of the charge accumulation section to a predetermined electric potential, the selection transistor controlling an output timing of the signal voltage, the conversion transistor controlling sensitivity of the signal voltage with respect to an amount of change in the signal charge.

(3)

The photoelectric conversion device according to (1), in which
the first semiconductor layer includes, for each of the pixels, a device isolation section that isolates the photoelectric converter, the charge accumulation section, and the transfer transistor, and
the pixel transistor is the amplification transistor, and is provided in a region of the device isolation section, the region being opposed to a portion where the first pixel and the second pixel are separated from each other.
   (4)

The photoelectric conversion device according to (3), in which the first gate wiring line and the second gate wiring line extend in a direction intersecting a direction in which the first gate wiring line and the second gate wiring line are opposed to each other with the pixel transistor being interposed therebetween.

(5)

The photoelectric conversion device according to (3), in which the first semiconductor layer further includes a conductive layer in a region that is opposed to the pixel transistor.

(6)

The photoelectric conversion device according to (5), in which
the wiring layer includes a vertical wiring line that electrically couples the charge accumulation section and the pixel transistor, and
the conductive layer is coupled to the vertical wiring line.
   (7)

The photoelectric conversion device according to (5), in which the conductive layer is floating.

(8)

The photoelectric conversion device according to (4), in which
the first gate wiring line is coupled to the gate of the transfer transistor of each of two or more of the pixels including the first pixel, and
the second gate wiring line is coupled to the gate of the transfer transistor of each of two or more of the pixels including the second pixel.
   (9)

An electronic apparatus including
a photoelectric conversion device including
   a first semiconductor layer in which a photoelectric converter, a charge accumulation section, and a transfer transistor are provided for each of pixels, the charge accumulation section accumulating signal charge generated at the photoelectric converter, the transfer transistor transferring the signal charge from the photoelectric converter to the charge accumulation section,
   a second semiconductor layer in which a pixel transistor is provided for each unit of one or more of the pixels, the pixel transistor reading out the signal charge from the charge accumulation section, the second semiconductor layer being stacked on the first semiconductor layer, and
   a wiring layer that is provided between the first semiconductor layer and the second semiconductor layer and in which a gate wiring line coupled to a gate of the transfer transistor is provided within an insulating layer for each of the pixels, in which
   the pixel transistor is disposed, in plan view, in a region between a first gate wiring line and a second gate wiring line in a first pixel and a second pixel being two of the pixels and being adjacent to each other, the first gate wiring line being coupled to the gate of the transfer transistor included in the first pixel, the second gate wiring line coupled to the gate of the transfer transistor included in the second pixel.

In the photoelectric conversion device according to the first aspect of the present disclosure and the electronic apparatus according to the second aspect of the present disclosure, the pixel transistor is disposed in the region between the first gate wiring line and the second gate wiring line in plan view. This reduces a possibility that a signal applied to the first gate wiring line or the second gate wiring line interferes with the pixel transistor, for example, as compared with a case where the first gate wiring line or the second gate wiring line is disposed directly below the pixel transistor. As a result, it is possible to suppress a deterioration in a noise characteristic of the pixel transistor. Note that the effects of the present technology are not necessarily limited to the effects described here, and may be any of the effects described herein.

This application claims the priority on the basis of Japanese Patent Application No. 2021-020561 filed on Feb. 12, 2021 with Japan Patent Office, the entire contents of which are incorporated in this application by reference.

It should be understood by those skilled in the art that various modifications, combinations, sub-combinations and alterations may occur depending on design requirements and other factors insofar as they are within the scope of the appended claims or the equivalents thereof

What is claimed is:

1. A photoelectric conversion device comprising:
a first semiconductor layer in which a photoelectric converter, a charge accumulation section, and a transfer transistor are provided for each of pixels, the charge accumulation section accumulating signal charge generated at the photoelectric converter, the transfer transistor transferring the signal charge from the photoelectric converter to the charge accumulation section;
a second semiconductor layer in which a pixel transistor is provided for each unit of one or more of the pixels, the pixel transistor reading out the signal charge from the charge accumulation section, the second semiconductor layer being stacked on the first semiconductor layer; and
a wiring layer that is provided between the first semiconductor layer and the second semiconductor layer and in which a gate wiring line coupled to a gate of the transfer transistor is provided within an insulating layer for each of the pixels, wherein
the pixel transistor is disposed, in plan view, in a region between a first gate wiring line and a second gate wiring line in a first pixel and a second pixel being two of the pixels and being adjacent to each other, the first gate wiring line being coupled to the gate of the transfer transistor included in the first pixel, the second gate wiring line coupled to the gate of the transfer transistor included in the second pixel.

2. The photoelectric conversion device according to claim 1, wherein the pixel transistor comprises at least one of an amplification transistor, a reset transistor, a selection transistor, or a conversion transistor, the amplification transistor generating a signal voltage corresponding to a level of the signal charge, the reset transistor resetting an electric potential of the charge accumulation section to a predetermined electric potential, the selection transistor controlling an output timing of the signal voltage, the conversion transistor controlling sensitivity of the signal voltage with respect to an amount of change in the signal charge.

3. The photoelectric conversion device according to claim 1, wherein
the first semiconductor layer includes, for each of the pixels, a device isolation section that isolates the photoelectric converter, the charge accumulation section, and the transfer transistor, and
the pixel transistor is the amplification transistor, and is provided in a region of the device isolation section, the region being opposed to a portion where the first pixel and the second pixel are separated from each other.

4. The photoelectric conversion device according to claim 3, wherein the first gate wiring line and the second gate wiring line extend in a direction intersecting a direction in which the first gate wiring line and the second gate wiring line are opposed to each other with the pixel transistor being interposed therebetween.

5. The photoelectric conversion device according to claim 3, wherein the first semiconductor layer further includes a conductive layer in a region that is opposed to the pixel transistor.

6. The photoelectric conversion device according to claim 5, wherein
the wiring layer includes a vertical wiring line that electrically couples the charge accumulation section and the pixel transistor, and
the conductive layer is coupled to the vertical wiring line.

7. The photoelectric conversion device according to claim 5, wherein the conductive layer is floating.

8. The photoelectric conversion device according to claim 4, wherein
the first gate wiring line is coupled to the gate of the transfer transistor of each of two or more of the pixels including the first pixel, and
the second gate wiring line is coupled to the gate of the transfer transistor of each of two or more of the pixels including the second pixel.

9. An electronic apparatus, comprising
a photoelectric conversion device including
a first semiconductor layer in which a photoelectric converter, a charge accumulation section, and a transfer transistor are provided for each of pixels, the charge accumulation section accumulating signal charge generated at the photoelectric converter, the transfer transistor transferring the signal charge from the photoelectric converter to the charge accumulation section,
a second semiconductor layer in which a pixel transistor is provided for each unit of one or more of the pixels, the pixel transistor reading out the signal charge from the charge accumulation section, the second semiconductor layer being stacked on the first semiconductor layer, and
a wiring layer that is provided between the first semiconductor layer and the second semiconductor layer and in which a gate wiring line coupled to a gate of the transfer transistor is provided within an insulating layer for each of the pixels, wherein
the pixel transistor is disposed, in plan view, in a region between a first gate wiring line and a second gate wiring line in a first pixel and a second pixel being two of the pixels and being adjacent to each other, the first gate wiring line being coupled to the gate of the transfer transistor included in the first pixel, the second gate wiring line coupled to the gate of the transfer transistor included in the second pixel.
